(19) United States
(12) Patent Application Publication
(10) Pub. No.: US 2026/0262452 A1
(43) Pub. Date: Sep. 3, 2026

(54) SUPERCONDUCTOR, SUPERCONDUCTING WIRE ROD, SUPERCONDUCTING BULK MAGNET AND SUPERCONDUCTING COIL ELECTROMAGNET

(71) Applicant: TOHOKU UNIVERSITY, Sendai-shi, Miyagi (JP)

(72) Inventors: Yuji MATSUMOTO, Sendai-shi (JP); Kenichi KAMINAGA, Sendai-shi (JP)

(21) Appl. No.: 18/873,478

(22) PCT Filed: Jun. 13, 2023
(86) PCT No.: PCT/JP2023/021942

§ 371 Date: Sep. 9, 2025

(30) Foreign Application Priority Data
Jun. 13, 2022 (JP) 2022-094963

(51) Int. Cl. H10N 60/85; C04B 35/01; C04B 35/50; H01B 12/00; H01F 6/00; H01F 6/06; H10N 60/83

(52) U.S. Cl. CPC H10N 60/855; C04B 35/016; C04B 35/50; H01B 12/00; H01F 6/00; H01F 6/06; H10N 60/83

(57) ABSTRACT

A superconductor having a perovskite-type crystal structure and represented by the following formula (I).

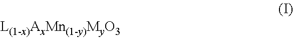

[In the formula (I), L represents one or more elements selected from lanthanides, A represents one or more elements selected from alkaline earth metals, Mn represents manganese, M represents one or more elements selected from platinum group elements, O represents oxygen, x represents a numerical value of 0 or more and 1 or less, and y represents a numerical value of 0.01 or more and 0.5 or less.]

### CROSS-REFERENCE TO RELATED APPLICATIONS

This application is the U.S. National Stage entry of International Application No. PCT/JP2023/021942, filed on Jun. 13, 2023, which, in turn, claims priority to JP Patent Application No. 2022-094963, filed on Jun. 13, 2022, both of which are hereby incorporated herein by reference in their entireties for all purposes.

### TECHNICAL FIELD

The present invention relates to a superconductor, a superconducting wire rod, a superconducting bulk magnet, and a superconducting coil electromagnet.

### BACKGROUND ART

After finding a superconductivity phenomenon of mercury in 1911, various superconductors have been found until today, and have been put into practical use as a superconducting magnet or a superconducting quantum interference device (SQUID).

In recent years, in a perovskite-type copper oxide compound group, a superconductor having a superconducting transition temperature (T) of more than 100 K under a normal pressure (about 0.1 MPa) has been found, and the possibility of implementing a room-temperature superconductor has increased.

For example, new superconductors such as an iron chalcogenide and a nickel oxide have been found, and there is a growing possibility of substances that can be used as a superconducting material (for example, see Non Patent Literatures 1 and 2). In addition, a copper oxide-based superconductor is also known.

### CITATION LIST

### Non Patent Literature

Non Patent Literature 1: Iron-Based Layered Superconductor La[O1−xFx]FeAs (x=0.05-0.12) with Tc=26 K, Y. Kamihara et al., J. Am. Chem. Soc. 130, 3296-3297 (2008).
Non Patent Literature 2: Superconductivity in an infinite-layer nickelate, D. Li et al., Nature 572, 624-628 (2019).

### SUMMARY OF INVENTION

### Technical Problem

However, each of the superconductors and the (1111)-type copper oxide-based superconductor according to NPLs 1 and 2 has a layered structure, and thus anisotropy of an upper critical field H_{c2} (a magnetic field when a superconducting state disappears) is strong, and alignment control of the crystal orientation is required when using polycrystals or thinning superconductors. Many of the (122)-type and (11)-type copper oxide superconductors do not have a high upper critical field anisotropy, and in such superconductors, alignment control of the crystal orientation is not required, but T_{c} under normal pressure is as low as about several tens of Kelvins, for example, about 40 K. It is difficult to put them into practical use as a superconducting magnet for a linear motor or the like.

Accordingly, an object of the present invention is to provide a superconductor that has a high upper critical field isotropy and does not require alignment control of a crystal orientation even under normal pressure, and a superconducting wire rod, a superconducting bulk magnet, and a superconducting coil electromagnet including the superconductor.

### Solution to Problem

As a result of intensive studies, the present inventors have found that a perovskite-type manganese oxide to which a platinum group element is added is a new superconductor that exhibits superconductivity under normal pressure. Further, the present inventors have found that these superconductors do not require alignment control of the crystal orientation because the upper critical field has an isotropy that does not depend on a magnetic field direction.

That is, the present invention has the following aspects.
[1]A superconductor having a perovskite-type crystal structure and represented by the following formula (I):

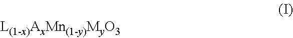

in which L represents one or more elements selected from lanthanides, A represents one or more elements selected from alkaline earth metals, Mn represents manganese, M represents one or more elements selected from platinum group elements, O represents oxygen, x represents a numerical value of 0 or more and 1 or less, and y represents a numerical value of 0.01 or more and 0.5 or less in the formula (I).
[2] The superconductor according to [1], in which M in the formula (I) represents iridium.
[3] The superconductor according to [1] or [2], in which L in the formula (I) represents lanthanum.
[4] The superconductor according to any of [1] to [3], in which A in the formula (I) represents strontium.
[5] The superconductor according to any of [1] to [4], which is a bulk body.
[6] The superconductor according to any of [1] to [4], which is a single crystal film.
[7] The superconductor according to any of [1] to [4], which is a polycrystalline film.
[8]A superconducting wire rod including the superconductor according to any of [1] to [7].
[9]A superconducting bulk magnet including the superconductor according to [5].
[10]A superconducting coil electromagnet including the superconducting wire rod according to [8].

### Advantageous Effects of Invention

According to the superconductor, the superconducting wire rod, the superconducting bulk magnet, and the superconducting coil electromagnet of the present invention, the isotropy is high, and the alignment control of the crystal orientation is not required even under a normal pressure.

### BRIEF DESCRIPTION OF DRAWINGS

FIG. 1 is a schematic diagram showing a crystal structure of a superconductor according to an embodiment of the present invention.

FIG. 2 is a schematic diagram of a production device of a superconductor according to the embodiment of the present invention.

FIG. 3 is a schematic diagram of a superconducting wire rod according to the embodiment of the present invention.

FIG. 4 is a schematic diagram of a superconducting wire rod according to a modification of FIG. 3.

FIG. 5 is a transmission electron microscope (TEM) photograph of a cross section of the superconductor according to the embodiment of the present invention.

FIG. 6 is a photograph showing energy dispersive X-ray analysis (EDX) results of a TEM image of the cross section of the superconductor according to the embodiment of the present invention.

FIG. 7 is a graph showing results of temperature dependence of resistivity of superconductors according to Examples 1 to 4 and a sample according to Comparative Example 1.

FIG. 8 is a graph showing results of temperature dependence of resistivity of superconductors according to Examples 5-1 to 5-6 and a sample according to Comparative Example 2.

FIG. 9 is a graph showing a correlation between a lattice volume and a superconducting transition temperature T_{c}^{on} of the superconductor according to Example 5-3 and a temperature T_{c}^{zero} at which the resistivity becomes zero (2×10⁻⁶ [Ω·cm] or less).

FIG. 10 is a graph showing results of temperature dependence of resistivity of superconductors according to Examples 6-1 and 6-2.

FIG. 11 is a graph showing results of temperature dependence of resistivity of superconductors according to Examples 7-1 and 7-2.

### DESCRIPTION OF EMBODIMENTS

### [Superconductor]

A superconductor according to the present invention is an inorganic oxide having a perovskite-type crystal structure and represented by the following formula (I).

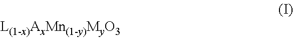

In the formula (I), L represents one or more elements selected from lanthanides. A represents one or more elements selected from alkaline earth metals. Mn represents manganese. M represents one or more elements selected from platinum group elements. O represents oxygen. x represents a numerical value of 0 or more and 1 or less. y is a numerical value of 0.01 or more and 0.5 or less.

In this description, the “superconductor” refers to an object exhibiting a phenomenon in which the electric resistance rapidly becomes zero at an extremely low temperature (for example, 0 K to 150 K (−273° C. to −123° C.) (superconducting transition phenomenon). The form of the superconductor is not particularly limited, and examples thereof include a bulk body and a thin film such as a single crystal film and a polycrystalline film.

In the formula (I), L represents one or more elements selected from lanthanides. The lanthanide is a rare earth element having an atomic number of 57 to 71, and represents any of lanthanum (La), cerium (Ce), praseodymium (Pr), neodymium (Nd), promethium (Pm), samarium (Sm), europium (Eu), gadolinium (Gd), terbium (TB), dysprosium (Dy), holmium (Ho), erbium (Er), thulium (Tm), ytterbium (Yb), and lutetium (Lu).

L in the formula (I) is preferably lanthanum, cerium, praseodymium, neodymium, samarium, europium, or gadolinium, more preferably lanthanum, cerium, praseodymium, or neodymium, and still more preferably lanthanum, from the viewpoint of obtaining a stable crystal structure. L in the formula (I) may be one element or two or more elements.

In the formula (I), A represents one or more elements selected from alkaline earth metals. The alkaline earth metal is a typical element belonging to Group 2 of the periodic table, and represents any of beryllium (Be), magnesium (Mg), calcium (Ca), strontium (Sr), barium (Ba), and radium (Ra).

A in the formula (I) is preferably strontium, calcium, or barium, and more preferably strontium, from the viewpoint of obtaining a stable crystal structure. A in the formula (I) may be one element or two or more elements.

In the formula (1), a combination (L, A) of L and A is preferably any of (La, Sr), (Pr, Sr), and (La, Sr).

In the formula (I), M represents one or more elements selected from platinum group elements. The platinum group element is an element located in Group 8 to Group 10 of the fifth period and the sixth period of the periodic table, and represents any of ruthenium (Ru), rhodium (Rh), palladium (Pd), osmium (Os), iridium (Ir), and platinum (Pt). Among these elements, the outermost electrons responsible for conduction occupy the 4d orbital or the 5d orbital.

M in the formula (I) is preferably rhodium, palladium, osmium, iridium, and platinum, more preferably iridium, osmium, and platinum, and particularly preferably iridium, from the viewpoint of further increasing T_{c}. M in the formula (I) may be one element or two or more elements. When the above more preferred element is selected as an element to substitute Mn, the site Mn_{(1-y)}M_{y} of Mn in the superconductor is a combination of an element in which the outermost electron responsible for conduction occupies the 3d orbital and an element in which the outermost electron responsible for conduction occupies the 5d orbital.

In the formula (I), x represents a ratio of the number of moles of A to a sum of the number of moles of A and the number of moles of L, and is a numerical value of 0 or more and 1 or less, preferably 0.1 or more and 0.9 or less, more preferably 0.2 or more and 0.8 or less, and still more preferably 0.3 or more and 0.7 or less. When x is within the above numerical range, the superconductor has a more stable crystal structure. When x is 0, it means that the superconductor does not have A in the formula (I). When x is 1, it means that the superconductor does not have L in the formula (I).

x is determined by inductively coupled plasma (ICP) analysis method. It is possible to adjust x by the type of L, the type of A, the mixing ratio between L and A, and the combination thereof.

In the formula (I), y represents a ratio of the number of moles of M to a sum of the number of moles of M and the number of moles of Mn, and is a numerical value of 0.01 or more and 0.5 or less, preferably 0.02 or more and 0.4 or less, more preferably 0.03 or more and 0.3 or less, still more preferably 0.05 or more and 0.3 or less, yet still more preferably 0.2 or less, and particularly preferably 0.15 or less or 0.13 or less. When y is within the above numerical range, T_{c} of the superconductor can be further increased. In addition, the superconductor exhibits high isotropy.

y is determined by the ICP analysis method. It is possible to adjust y by the type of M, the mixing ratio between M and Mn, the production conditions of the superconductor, and the combination thereof.

The superconductor according to the present embodiment has a perovskite-type crystal structure.

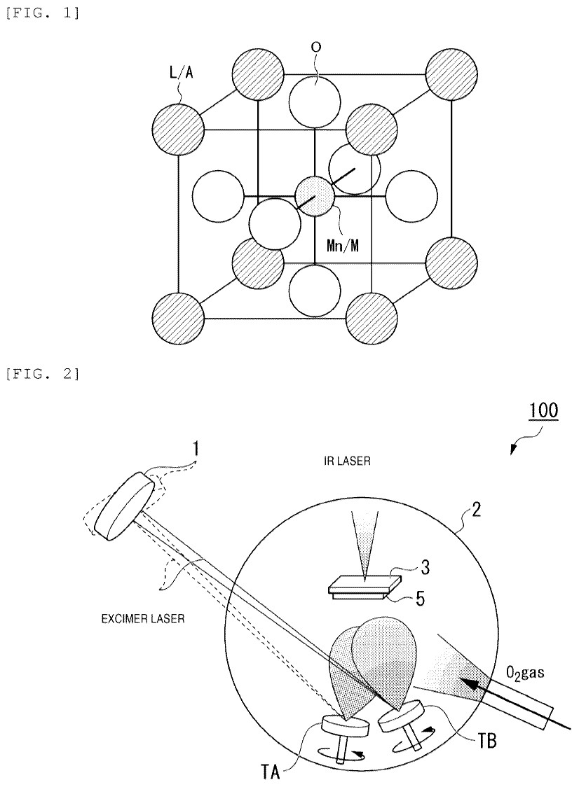

As shown in FIG. 1, the superconductor according to the present embodiment has a cubic unit lattice. One or more elements (L/A) selected from L and A are located at each vertex of the cubic crystal, one or more elements (Mn/M) selected from Mn and M are located at a body center, and O (oxygen) is located at a center of each plane of the cubic crystal.

In the perovskite-type crystal structure, a position occupied by the element at each vertex is referred to as an A site, and a position occupied by the element of the body center is referred to as a B site. A compound having a perovskite-type crystal structure is generally represented by ABO₃ where A represents an element located at the A site and B represents an element located at the B site. In the present embodiment, L/A is located at the A site, and Mn/M is located at the B site.

The orientation of an octahedron made of oxygen and Mn/M is more distorted by the interaction with L/A, and the cubic crystal undergoes phase transition to an orthorhombic crystal or a tetragonal crystal having lower symmetry.

The T_{c} of the superconductor according to the present embodiment at normal pressure is, for example, preferably 50 K or higher, more preferably 77 K or higher, and still more preferably 100 K or higher. When T_{c} at normal pressure is equal to or greater than the above lower limit value, the possibility of practical use of the superconductor as a high-temperature superconductor (for example, a superconductor that exhibits a superconducting transition phenomenon at 77 K or more) can be further increased. An upper limit value of T_{c} at normal pressure is not particularly limited.

T_{c} at normal pressure of the superconductor is determined, for example, by measuring the resistivity at an extremely low temperature.

The T_{c} of the superconductor at normal pressure can be adjusted by the type of L, the type of A, the type of M, the value of x, and the value of y in the formula (I), the production conditions of the superconductor, and a combination thereof.

The isotropic parameter y of the superconductor according to the present embodiment is, for example, preferably 0.5 to 2.5, more preferably 0.7 to 2.0, and still more preferably 0.9 to 1.5. When the isotropic parameter of the superconductor is within the above numerical range, the isotropy is more excellent, and alignment control of the crystal orientation with respect to the magnetic field cannot be required.

The isotropic parameter of the superconductor is a value calculated by measuring an upper critical field H_{c2}^{//} in an in-plane direction and an upper critical field H_{c2}^{⊥} in a direction perpendicular to a plane which is a direction perpendicular to the in-plane direction with respect to a measurement sample having a planar shape, according to the following formula (2).

$$( Isotropic parameter ) = ( upper critical field ( T ) in in - plane direction ) / ( upper critical field ( T ) in direction perpendicular to plane ) \qquad ( 2 )$$

The isotropic parameter of the superconductor can be adjusted according to the type of L, the type of A, the type of M, the value of x, and the value of y in the formula (I), the production conditions of the superconductor, and a combination thereof.

Examples of the perovskite-type crystal structure include a (1,1,3) type, a (2,1,4) type, a (3,2,7) type, and a (4,3,10) type shown in FIG. 1. These crystal structures show a layered perovskite-type crystal structure and can form superconductors, and the (1,1,3) type crystal structure is preferred because it is more stable and has excellent isotropy.

Here, the (1,1,3) type indicates that a ratio of the number of moles of the element located at the A site to the number of moles of the element located at the B site, and the number of moles of oxygen is 1:1:3 (ABO₃). Similarly, the (2,1,4) type represents that a ratio of the number of moles of the element located at the A site, the number of moles of the element located at the B site, and the number of moles of oxygen is 2:1:4 (A₂BO₄), the (3,2,7) type represents that a ratio of the number of moles of the element located at the A site, the number of moles of the element located at the B site, and the number of moles of oxygen is 3:2:7 (A₃B₂O₇), and the (4,3,10) type represents that a ratio of the number of moles of the element located at the A site, the number of moles of the element located at the B site, and the number of moles of oxygen is 4:3:10 (A₄B₃O₁₀).

In any of the compositions, the ratio of elements in the composition is determined by the ICP analysis method.

The (2,1,4) type composition is represented by the following formula (II).

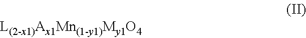

In the formula (II), the elements L, A, and M are the same as the elements L, A, and M in the superconductor represented by the formula (I).

In the formula (II), x1 represents a ratio of the number of moles of A to a sum of the number of moles of A and the number of moles of L, and is a numerical value of 0 or more and 2 or less, preferably 0.2 or more and 1.8 or less, more preferably 0.4 or more and 1.6 or less, and still more preferably 0.6 or more and 1.4 or less.

In the formula (II), y1 represents a ratio of the number of moles of M to a sum of the number of moles of M and the number of moles of Mn, and is a numerical value of 0.01 or more and 0.5 or less, preferably 0.02 or more and 0.4 or less, more preferably 0.03 or more and 0.3 or less or 0.05 or more and 0.3 or less, still more preferably 0.2 or less, and particularly preferably 0.15 or less or 0.13 or less.

The (3,2,7) type composition is represented by the following formula (III).

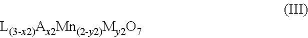

In the formula (III), the elements L, A, and M are the same as the elements L, A, and M in the superconductor represented by the formula (I).

In the formula (III), x2 represents a ratio of the number of moles of A to a sum of the number of moles of A and the number of moles of L, and is a numerical value of 0 or more and 3 or less, preferably 0.3 or more and 2.7 or less, more preferably 0.6 or more and 2.4 or less, and still more preferably 0.9 or more and 2.1 or less.

In the formula (III), y2 represents a ratio of the number of moles of M to a sum of the number of moles of M and the number of moles of Mn, and is a numerical value of 0.02 or more and 1.0 or less, preferably 0.04 or more and 0.8 or less, more preferably 0.06 or more and 0.6 or less or 0.1 or more and 0.6 or less, still more preferably 0.4 or less, and particularly preferably 0.3 or less or 0.25 or less.

The (4,3,10) type composition is represented by the following formula (IV).

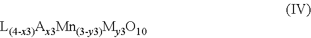

In the formula (IV), the elements L, A, and M are the same as the elements L, A, and M in the superconductor represented by the formula (I).

In the formula (IV), x3 represents a ratio of the number of moles of A to a sum of the number of moles of A and the number of moles of L, and is a numerical value of 0 or more and 4 or less, preferably 0.4 or more and 3.6 or less, more preferably 0.8 or more and 3.2 or less, and still more preferably 1.2 or more and 2.8 or less.

In the formula (IV), y3 represents a ratio of the number of moles of M to a sum of the number of moles of M and the number of moles of Mn, and is a numerical value of 0.03 or more and 1.5 or less, preferably 0.06 or more and 1.2 or less, more preferably 0.09 or more and 0.9 or less or 0.15 or more and 0.9 or less, still more preferably 0.6 or less, and particularly preferably 0.45 or less or 0.4 or less.

### <<Method for Producing Superconductor>>

The superconductor according to the present embodiment can be produced, for example, by depositing a film on a specific substrate.

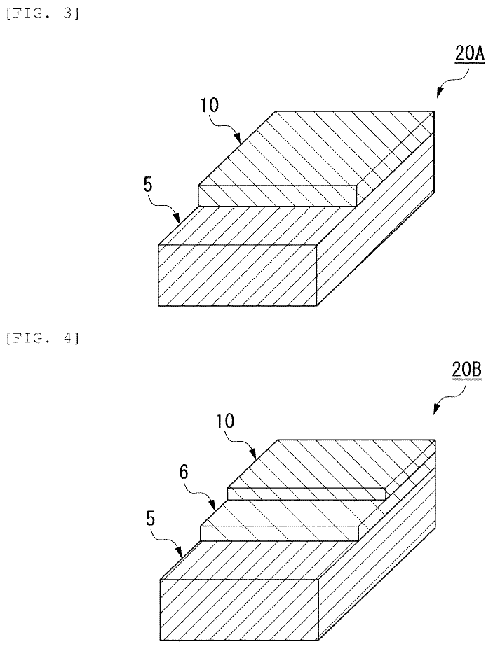

FIG. 2 is a schematic diagram of a production device of the superconductor according to the present embodiment.

As shown in FIG. 2, a production device 100 of the superconductor according to the present embodiment includes a galvanometer mirror 1, a film deposition chamber (chamber) 2, and an alloy plate 3 for heating a substrate 5. Two targets that are targets TA and TB and the substrate 5 are disposed in the film deposition chamber (chamber) 2.

Raw materials having different M concentrations are set in the targets TA and TB.

In the present description, the “galvanometer mirror” refers to a reflection mirror that can control a laser beam in any direction at a high speed and can emit the laser beam at a pinpoint.

Examples of the raw materials set as the targets TA and TB include inorganic manganese oxide powders and granules (pellets) having L/A, Mn/M, and O. The ratio of L/A and the ratio of Mn/M can be freely set according to the desired performance of the superconductor.

L in the raw material is, for example, preferably lanthanum, cerium, praseodymium, neodymium, samarium, europium, or gadolinium, more preferably lanthanum, cerium, praseodymium, or neodymium, and still more preferably lanthanum, from the viewpoint of obtaining a stable crystal structure.

A in the raw material is, for example, preferably strontium, calcium, or barium, and more preferably strontium, from the viewpoint of obtaining a stable crystal structure.

The combination of L/A in the raw material is preferably any of La/Sr, Pr/Sr, and La/Sr.

M in the raw material is, for example, preferably iridium, osmium, and platinum, and more preferably iridium, from the viewpoint of further increasing T_{c}.

A method (galvanometer scanning pulsed laser deposition method) for producing a superconductor using the production device shown in FIG. 2 will be described.

First, an excimer laser or a solid-state laser is emitted to the galvanometer mirror 1, and reflected light is emitted to the targets TA and TB.

Examples of the excimer laser include an argon fluorine (ArF) excimer laser (oscillation wavelength: 193 nm), a krypton fluorine (KrF) excimer laser (oscillation wavelength: 248 nm), a xenon chlorine (XeCl) excimer laser (oscillation wavelength: 308 nm), and a xenon fluorine (XeF) excimer laser (oscillation wavelength: 351 nm).

The excimer laser is preferably an ArF excimer laser, a KrF excimer laser, an XeCl excimer laser, or an XeF excimer laser, and more preferably a KrF excimer laser, from the viewpoint of promoting the emission of atoms in the raw material.

Examples of the solid-state laser include a neodymium-doped yttrium aluminum garnet (Nd: YAG) laser (oscillation wavelength of quadrupling wave: 266 nm).

The atoms of the raw material emitted by the excimer laser or the solid-state laser reach a surface of the substrate 5, and the irradiation with the excimer laser or the solid-state laser is continued, so that a thin film is formed on the surface of the substrate 5. The thin film may be a single crystal film made of a single crystal or a polycrystalline film in which two or more crystals are combined.

The thin film is preferably a polycrystalline film because of more excellent industrial applicability thereof.

The thickness of the thin film of the superconductor is, for example, preferably 10 nm to 200 nm, more preferably 50 nm to 170 nm, and still more preferably 100 nm to 150 nm. When the film thickness is equal to or greater than the above lower limit value, the isotropy of the superconductor can be further increased. When the film thickness is equal to or less than the above upper limit value, the physical strength of the superconductor can be further increased.

The thickness of the thin film of the superconductor is determined by, for example, observing a cross section of the thin film in a thickness direction with an electron microscope.

Examples of the substrate 5 include an LSAT substrate, an STO substrate, an LAO substrate, a DSO substrate, an LSAO substrate, an NGO substrate, a KTO substrate, and an MgO substrate. The LSAT substrate is a substrate made of a metal oxide containing lanthanum, aluminum, strontium, and tantalum as elements. The STO substrate is a substrate made of a metal oxide containing strontium and titanium as elements. The LAO substrate is a substrate made of a metal oxide containing lanthanum and aluminum as elements. The DSO substrate is a substrate made of a metal oxide containing dysprosium and scandium as elements. The LSAO substrate is a substrate made of a metal oxide containing lanthanum, strontium, and aluminum as elements. The NGO substrate is a substrate made of a metal oxide containing neodymium and gallium as elements. The KTO substrate is a substrate made of a metal oxide containing potassium and tantalum as elements. The MgO substrate is a substrate made of a metal oxide containing magnesium as an element.

As the substrate 5, an LSAT substrate is preferred because a superconductor having a stable crystal structure is easily obtained, and an LSAT substrate or an STO substrate is preferably used because a superconductor having a high superconducting transition temperature at normal pressure is easily obtained.

The film deposition of the superconductor is preferably performed while supplying oxygen gas to the film deposition chamber 2. Oxygen is sufficiently bonded, and a superconductor having a more stable crystal structure can be obtained by depositing a film of the superconductor while supplying oxygen gas to the film deposition chamber 2.

The partial pressure of the oxygen gas supplied to the film deposition chamber 2 is preferably, for example, 1 mTorr to 1000 mTorr (0.13 Pa to 133.3 Pa), more preferably 10 mTorr to 500 mTorr (1.3 Pa to 66.7 Pa), and still more preferably 20 mTorr to 100 mTorr (2.7 Pa to 13.3 Pa). When the partial pressure of the oxygen gas supplied to the film deposition chamber 2 is equal to or greater than the above lower limit value, oxygen is sufficiently bonded, and a superconductor having a more stable crystal structure can be obtained. When the partial pressure of the oxygen gas supplied to the film deposition chamber 2 is equal to or less than the above upper limit value, the supply of excessive oxygen can be prevented, and the amount of oxygen used can be reduced.

The partial pressure of the oxygen gas supplied to the film deposition chamber 2 can be determined from, for example, a pressure gauge attached to an oxygen cylinder.

The time of film deposition of the superconductor is, for example, preferably 10 minutes to 150 minutes, more preferably 60 minutes to 120 minutes, and still more preferably 90 minutes to 110 minutes. When the film deposition time is equal to or greater than the above lower limit value, a thin film having a sufficient thickness can be obtained. When the film deposition time is equal to or less than the above upper limit value, the productivity of the superconductor can be further increased. Here, the film deposition time refers to the time from the start of the irradiation with the excimer laser or the solid-state laser to the stop of the irradiation.

The temperature (film deposition temperature) of the substrate 5 during deposition of the superconductor is, for example, preferably 650 K to 1000 K, more preferably 700 K to 900 K, and still more preferably 750 K to 810 K. When the film deposition temperature is within the above numerical range, a superconductor having a more stable crystal structure can be obtained.

For example, as shown in FIG. 2, the alloy plate 3 for heating the substrate 5 is disposed on a back side of a film deposition surface of the substrate 5, and an infrared ray (IR) laser for heating the substrate is emitted to the alloy plate 3, so that the alloy plate 3 absorbs the infrared ray and the substrate 5 can be heated to a desired film deposition temperature. The film deposition temperature can be adjusted by the irradiation intensity of the IR laser, the irradiation time of the IR laser, and the like.

Examples of the alloy plate 3 include a plate obtained by processing a nickel alloy such as Inconel (registered trademark).

The method of heating the substrate 5 is not limited to the method using the IR laser, and may be, for example, a heating method using a heating wire, and a heating method using a lamp (infrared radiation lamp or the like).

The pressure (film deposition pressure) in the film deposition chamber 2 during deposition of the superconductor is preferably, for example, 1 mTorr to 1000 mTorr (0.13 Pa to 133.3 Pa), more preferably 10 mTorr to 500 mTorr (1.3 Pa to 66.7 Pa), and still more preferably 20 mTorr to 100 mTorr (2.7 Pa to 13.3 Pa). When the film deposition pressure is within the above numerical range, a superconductor having a more stable crystal structure can be obtained.

The targets TA and TB can be divided at a high speed by using the galvanometer mirror 1. Therefore, the ratio of Mn/M (y in the formula (I)) can be easily adjusted, and the film deposition time can be shortened.

The superconductor may be deposited by directly irradiating a target with a pulsed laser (excimer laser or solid-state laser) without using the galvanometer mirror 1 (pulsed laser deposition method).

FIG. 2 shows an example in which raw materials having different compositions are set as the two targets, TA and TB, and the reflected light is split between the two targets, TA and TB, but the present invention is not limited to the above example. That is, in the present embodiment, a superconductor may be formed by setting one kind of raw material as one target and emitting a pulsed laser or reflected light the one target. That is, in the method of producing a superconductor according to the present embodiment, one or more kinds of raw materials are set as a target or targets, and a pulsed laser or reflected light is emitted to one or more kinds of targets.

The superconductor may be a bulk body instead of a thin film. An application to a superconducting magnet described below can be made easier by forming the bulk body. In addition, the thin film described above can be produced using a bulk body as a raw material.

In the present description, the “bulk body” refers to a sintered body or a melt-grown body ceramics or the like. The bulk body is obtained by, for example, sintering a mixture of powders which are raw materials of the thin film. Specifically, for example, in the case of Ir-doped LaSrMnO₃ (LaSrMnIrO₃), powders of lanthanum oxide (La₂O₃), strontium carbonate (SrCO₃), manganese dioxide (MnO₂), and iridium oxide (IrO₂), which are raw materials, are weighed so as to have a stoichiometric ratio, sufficiently mixed in a mortar, and then compressed by applying a pressure of 40 MPa to 50 MPa using a press machine to form pellets. Thereafter, the pellets are fired in an electric furnace at 1050° C. to 1150° C. for 12 hours, then pulverized, and remolded into pellets shape, followed by firing at 1150° C. to 1250° C. for 24 hours. In addition, the bulk body may be produced by, for example, a floating zone method (FZ method). In particular, the single crystal bulk body is preferably produced by the FZ method. The FZ method refers to a method in which a part of a polycrystalline sample rod serving as a raw material is heated to form a molten portion between a lower single crystal serving as a seed crystal and the sample rod, the entire molten portion is moved downward, and the molten portion is cooled to obtain a single crystal.

### [Superconducting Wire Rod]

The superconducting wire rod according to the present invention includes the superconductor according to the present invention.

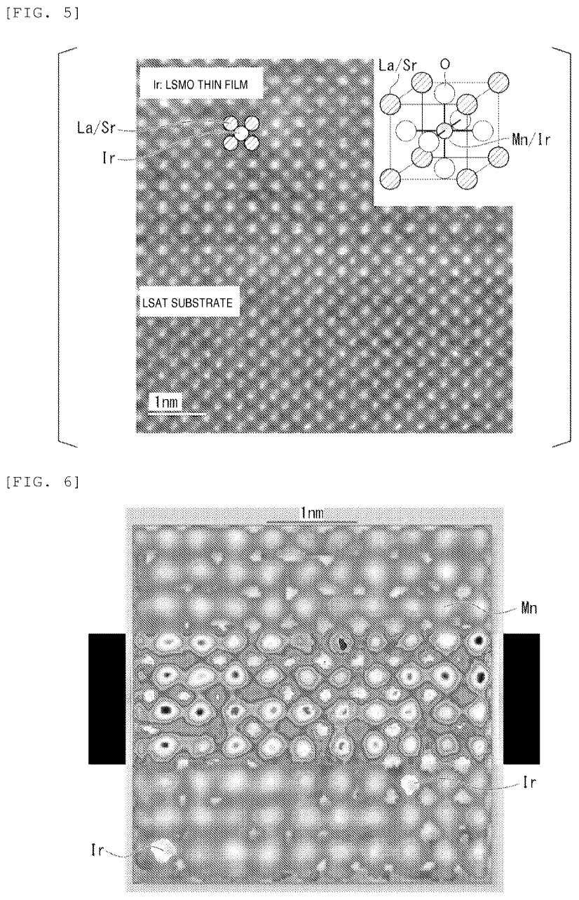

Examples of the superconducting wire rod include a wire rod using the superconductor according to the present invention as a superconducting layer of the superconducting wire rod. FIG. 3 is a schematic diagram of a superconducting wire rod according to an embodiment of the present invention, and FIG. 4 is a schematic diagram of a superconducting wire rod according to a modification of FIG. 3. A superconducting wire rod 20A shown in FIG. 3 includes the substrate 5 and a superconducting layer 10 formed in contact with an upper surface of the substrate 5. A superconducting wire rod 20B shown in FIG. 4 includes the substrate 5, an intermediate layer 6 formed on the substrate 5, and the superconducting layer 10 formed in contact with an upper surface of the intermediate layer 6.

Generally, it is necessary to control the orientation of the superconducting layer in a production process of the superconducting wire rod. For example, the orientation of the superconducting layer may be controlled using a method of performing rolling during heating or a method of precipitating the superconductor from a molten state. In particular, a method of depositing an intermediate layer for controlling the orientation of the superconducting layer between the substrate and the superconducting layer is often used. A structure of the superconducting wire rod produced by such a method is as shown in FIG. 4.

However, when the superconductor according to the present invention is used as the superconducting layer, alignment control is not required. For example, when the superconductor according to the present invention is used as a superconducting layer, the superconducting wire rod according to the present invention does not require an intermediate layer. That is, the superconducting wire rod having the structure shown in FIG. 3 can be produced. Therefore, the production process of the superconducting wire rod can be simplified, and the raw material cost can be reduced. The superconducting wire rod according to the present invention may include an intermediate layer.

The superconducting wire rod can be expected to be applied to a power transmission line or the like capable of reducing electric loss during power transmission.

### [Superconducting Bulk Magnet]

The superconducting bulk magnet according to the present invention includes the superconductor according to the present invention, which is a bulk body.

Examples of the superconducting bulk magnet include a magnet obtained by sintering a raw material for forming a polycrystalline film and molding the sintered raw material into a disk shape.

The superconducting bulk magnet can be expected to be applied to a magnetic separation device, a flywheel energy storage device, a super powerful motor, and the like.

### [Superconducting Coil Electromagnet]

The superconducting coil electromagnet according to the present invention includes the superconducting wire rod according to the present invention.

Examples of the superconducting coil electromagnet include an electromagnet obtained by molding a superconducting wire rod into a coil shape.

The superconducting coil electromagnet can be expected to be applied to nuclear magnetic resonance spectroscopy (NMR) that does not use liquid helium, nuclear magnetic resonance imaging (MRI) that does not use liquid helium, a maglev train such as a linear motor car, and the like.

The superconductor according to the present embodiment has a perovskite-type crystal structure in which a part of manganese is substituted with a platinum group element, and therefore, the superconductor has an isotropy and does not require alignment control of a crystal orientation with respect to a magnetic field.

In the superconductor according to the present embodiment, the ratio of the number of moles of the platinum group element to the sum of the number of moles of the platinum group element and the number of moles of Mn is 0.01 or more and 0.5 or less, and therefore, T_{c} can be increased, and the possibility of using the superconductor as a high-temperature superconductor can be further increased.

The superconductor according to the present embodiment is used for the superconducting wire rod according to the present embodiment, and therefore, the alignment control of the crystal orientation with respect to the magnetic field is not required, and the possibility of practical use can be further increased.

The superconductor according to the present embodiment is used for the superconducting bulk magnet according to the present embodiment, and therefore, the alignment control of the crystal orientation with respect to the magnetic field is not required, and the possibility of practical use can be further increased.

The superconductor according to the present embodiment is used for the superconducting coil electromagnet according to the present embodiment, and therefore, the alignment control of the crystal orientation with respect to the magnetic field is not required, and the possibility of practical use can be further increased.

### EXAMPLES

The present invention will be described in more detail below using Examples. However, the present invention is not limited to these Examples.

### Example 1

As a raw material of the superconductor, a pellet-shaped manganese oxide having L=La, A=Sr, M=Ir, x=0.3, and y=0 in the formula (I) was used and set as a target TA. That is, a composition represented by a composition formula La_{0.7}Sr_{0.3}MnO₃ was set as the target TA. Similarly, a pellet-shaped manganese oxide having L=La, A=Sr, M=Ir, x=0.3, and y=0.05 in the formula (I) was used and set as a target TB. That is, a composition represented by a composition formula La_{0.7}Sr_{0.3}Mn_{0.95}Ir_{0.05}O₃ was set as the target TB.

Under normal pressure, a KrF excimer laser (oscillation wavelength: 248 nm) was emitted to a galvanometer mirror for 100 minutes under an environment at 25° C., and was split at a high speed between the above targets TA and TB, a thin film (single crystal film, film thickness: 150 nm) in which the number of moles of iridium to the total number of moles of manganese and iridium (hereinafter, also referred to as iridium concentration) was adjusted to 1.8% was deposited (epitaxially grown) by the galvanometer scanning pulsed laser deposition method.

A c-plane LSAT substrate having a composition of (LaAlO₃)_{0.3}—(SrAl_{0.5}Ta_{0.5}O₃)_{0.7} was used as a substrate on which a film is to be deposited, and during film deposition, oxygen gas at 50 mTorr (6.7 Pa) was supplied to a film deposition chamber. During the film deposition, a nickel alloy plate was disposed on a surface of the LSAT substrate opposite to the film deposition surface, and the alloy plate was irradiated with an IR laser of 18 W to indirectly heat the LSAT substrate. The surface temperature of the LSAT substrate during film deposition was 530° C.

### Example 2

A thin film (single crystal film, film thickness: 130 nm) having an iridium concentration adjusted to 7.3% was deposited in the same manner as in Example 1 except that a pellet-shaped manganese oxide having y=0.05 in the formula (I) was used as a raw material of the superconductor and set as a target TA, and a pellet-shaped manganese oxide having y=0.21 in the formula (I) was used and set as a target TB. That is, in Example 2, a composition represented by a composition formula La_{0.7}Sr_{0.3}Mn_{0.95}Ir_{0.05}O₃ was set as the target TA, and a composition represented by a composition formula La_{0.7}Sr_{0.3}Mn_{0.79}Ir_{0.21}O₃ was set as the target TB.

### Example 3

A thin film (single crystal film, film thickness: 120 nm) having an iridium concentration adjusted to 11.0% was deposited in the same manner as in Example 1, except that a pellet-shaped manganese oxide having y=0.11 in the formula (I) was used as a raw material of the superconductor and set as the target TA, the raw material was not set as the target TB, and the splitting to the targets TA and TB was not performed. That is, in Example 3, a composition represented by a composition formula La_{0.7}Sr_{0.3}Mn_{0.89}Ir_{0.11}O₃ was set as the target TA, and only the target TA was irradiated with a KrF excimer laser.

### Example 4

A thin film (single crystal film, film thickness: 150 nm) having an iridium concentration adjusted to 19.3% was deposited in the same manner as in Example 1, except that a pellet-shaped manganese oxide having y=0.23 in the formula (I) was used as a raw material of the superconductor and set as the target TA, the raw material was not set as the target TB, and the splitting to the targets TA and TB was not performed. That is, in Example 4, a composition represented by a composition formula La_{0.7}Sr_{0.3}Mn_{0.77}Ir_{0.23}O₃ was set as the target TA, and only the target TA was irradiated with a KrF excimer laser.

### Comparative Example 1

A thin film (single crystal film, film thickness: 130 nm) having an iridium concentration adjusted to 0% was deposited in the same manner as in Example 1, except that a pellet-shaped manganese oxide having y=0 in the formula (I) was used as a raw material of the superconductor and set as the target TA, the raw material was not set as the target TB, and the splitting to the targets TA and TB was not performed. That is, in Comparative Example 1, a composition represented by a composition formula La_{0.7}Sr_{0.3}MnO₃ was set as the target TA, and only the target TA was irradiated with a KrF excimer laser.

### (ICP Analysis)

In order to determine y in the formula (I), ICP analysis was performed on the samples in Examples 1 to 4 and Comparative Example 1 under the following conditions. As a result, in Example 1, Example 2, Example 3, and Example 4, y=0.018, 0.073, 0.11, and 0.193, respectively. In addition, x in the formula (I) determined by the ICP analysis of the sample in Example 3 was 0.30. That is, it was found that the Sr concentration in the A site was 30% in the above Example 3 in which the manganese oxide having the composition ratio at the A site of La:Sr=7:3 was used as the target.

### (TEM Observation)

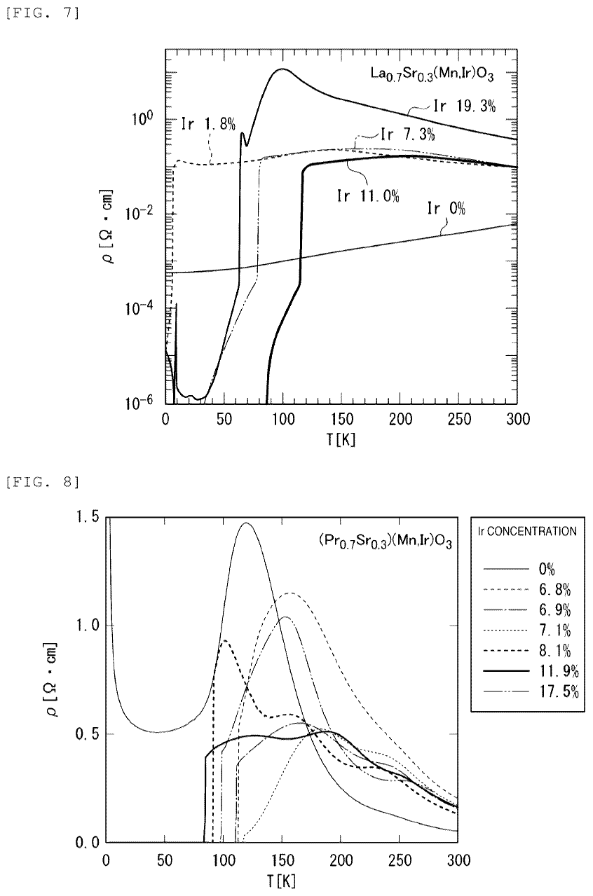

A cross section of the obtained thin film (iridium concentration: 7.3%) in Example 2 was observed by TEM. A TEM image is shown in FIG. 5, and an EDX image of the TEM image is shown in FIG. 6. In FIG. 5, a crystal structure of a unit lattice of the superconductor in Example 2 is also shown on the upper right of the drawing, and a La or Sr atom and O atoms are shown in the TEM image.

As shown in FIG. 5, it was found that a thin film (Ir:LSMO thin film) of LaSrMnO containing iridium was deposited on the LSAT substrate in an orderly manner.

As shown in FIG. 6, it was found that a part of manganese located at the body center was substituted with iridium.

### (Resistivity Measurement)

Regarding the thin film of each example, the resistivity was measured by flowing a current of 1000 μA while decreasing the temperature using liquid helium under normal pressure. The results are shown in FIG. 7.

As shown in FIG. 7, the thin film in Comparative Example 1 (iridium concentration: 0%) did not exhibit a superconducting transition phenomenon. It was found from this result that the thin film in Comparative Example 1 was not a superconductor.

In the thin films (iridium concentrations: 1.8%, 7.3%, 11.0%, and 19.3%) of Examples 1 to 4, a phenomenon (superconducting transition phenomenon) in which the resistivity rapidly becomes zero in the process of decreasing the temperature was found. It was found from the results that the thin films in Examples 1 to 4 function as superconductors.

In addition, as shown in FIG. 7, it was found that the superconducting transition temperature (T_{c}) of the thin film (iridium concentration: 11.0%) in Example 3 was the highest and was about 123 K. It was found that T_{c} was about 9 K in the case of the thin film in Example 1 (iridium concentration: 1.8%), T_{c} was about 83 K in the case of the thin film in Example 2, and T_{c} was about 67 K in the case of the thin film in Example 4 (iridium concentration: 19.3%).

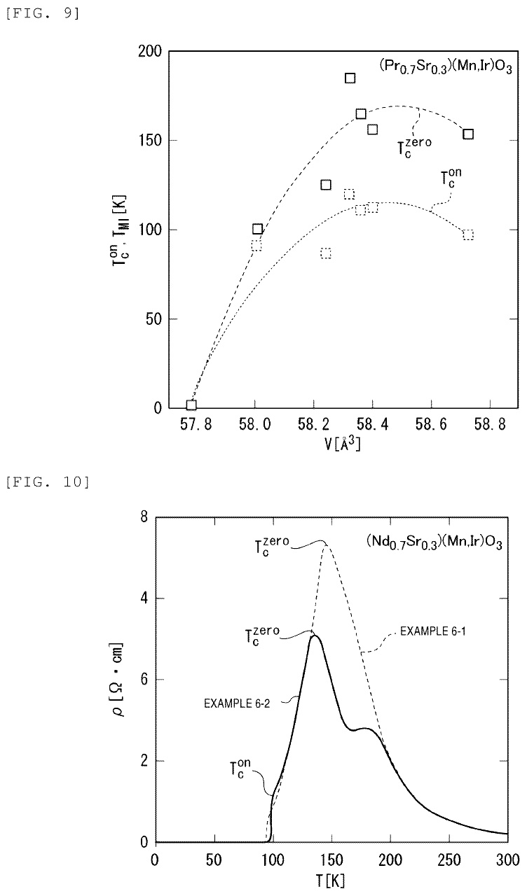

Regarding the thin film in each example, a superconducting transition temperature (hereinafter, also referred to as “T_{c}^{on}”), a temperature (hereinafter, also referred to as “T_{c}^{zero}”) at which the resistivity becomes zero (2×10⁻⁶ [Ω·cm] or less), an upper critical field in an in-plane direction (hereinafter, also referred to as “μ₀H_{c2}^{//}(0)”), and an upper critical field in a direction perpendicular to the plane (hereinafter, also referred to as “μ₀H_{c2}^{⊥}(0)”) were measured. Since the c-plane LSAT substrate is used as the substrate, the upper critical field in the in-plane direction corresponds to the upper critical field μ₀H_{c2}^{∥ab}(0) in the direction parallel to the c-plane, and the upper critical field in the direction perpendicular to the plane corresponds to the upper critical field μ₀H_{c2}^{μc}(0) in a c-axis direction. An isotropic parameter was calculated from values of μ₀H_{c2}^{//}(0) and μ₀H_{c2}^{⊥}(0) based on the following formula (3). Results are shown in FIG. 8. In FIG. 8, “-” indicates that T_{c}^{zero} was not observed.

$$( Isotropic parameter ) = ( {μ}_{0} {H}_{c 2} // ( 0 ) ) / ( {μ}_{0} {H}_{c 2} ⊥ ( 0 ) ) \qquad ( 3 )$$

In the formula (3), μ₀ represents the vacuum permeability, and H_{c2} represents the magnitude of the upper critical field. Data in which the symbol “-” is written in the table is data that was not measured.

TABLE 1

| | | | Temperature | Upper critical | Upper critical field | |
|---|---|---|---|---|---|---|
| | Ir | Superconducting | at which | field in | in direction | Isotropic |
| | concentration | transition | resistivity | in-plane | perpendicular to | parameter |
| | at B site | temperature | becomes 0 | direction | plane | H_{c2}^{//}(0)/ |
| | Ir % | T_{c}^{on} [K] | T_{c}^{zero} [K] | μ₀H_{c2}^{//}(0) [T] | μ₀H_{c2}^{⊥}(0) [T] | H_{c2}^{⊥}(0) |
| Example | 1.8 | 9 | — | 3.4 | 3.5 | 0.96 |
| 1 | | | | | | |
| Example | 7.3 | 83 | 31 | 26 | 21 | 1.3 |
| 2 | | | | | | |
| Example | 11.0 | 123 | 86 | 401 | 348 | 1.2 |
| 3 | | | | | | |
| Example | 19.3 | 67 | 32 | 426 | 216 | 2.0 |
| 4 | | | | | | |

As shown in Table 1, it was found that the thin films of Examples 1 to 4 had isotropic parameter values of 0.96 to 2.0 and were excellent in the isotropy because the isotropic parameter values were close to 1. It was found that the thin films in Examples 1 to 3 had isotropic parameter values of 0.96 to 1.3 and were particularly excellent in the isotropy. In the compositions in which (La, Sr) was used and the B site was (Mn, Ir) as in Examples 1 to 4, it is considered that y in the formula (I) is preferably 0.02 or more and 0.2 or less, more preferably 0.02 or more and 0.15 or less, and still more preferably 0.05 or more and 0.13 or less.

The superconducting transition phenomenon could not be observed in the thin film in Comparative Example 1, and therefore, the upper critical field could not be measured. Therefore, the isotropic parameter of the thin film in Comparative Example 1 could not be calculated.

### Example 5-1

A composition represented by a composition formula Pr_{0.7}Sr_{0.3}Mn_{0.90}Ir_{0.10}O₃ was set as only one target TA.

Under normal pressure, only the target TA was irradiated with a KrF excimer laser (oscillation wavelength: 248 nm) via a galvanometer mirror for 100 minutes under an environment at 25° C., and a thin film (single crystal film) having an iridium concentration adjusted to 6.8% was deposited (epitaxially grown) by the galvanometer scanning pulsed laser deposition method.

A c-plane LSAT substrate having a composition of (LaAlO₃)_{0.3}—(SrAl_{0.5}Ta_{0.5}O₃)_{0.7} was used as a substrate on which a film is to be deposited, and during film deposition, oxygen gas at 50 mTorr (6.7 Pa) was supplied to a film deposition chamber. During the film deposition, a nickel alloy plate was disposed on a surface of the LSAT substrate opposite to the film deposition surface, and the alloy plate was irradiated with an IR laser of 18 W to indirectly heat the LSAT substrate. The surface temperature of the LSAT substrate during film deposition was 530° C.

### Examples 5-2 to 5-6

Thin films were deposited in the same manner as in Example 5-1 except that the composition ratios of the composition set as the target TA were changed.

### Comparative Example 2

A thin film (single crystal film) having an iridium concentration adjusted to 0% was deposited as in Example 5-1 except that, as a raw material of the superconductor, a composition represented by a composition formula Pr_{0.7}Sr_{0.3}MnO₃ was set as the target TA. That is, in Comparative Example 2, only the target TA was irradiated with a KrF excimer laser.

### (ICP Analysis)

In order to determine x and y in the formula (I), ICP analysis was performed on the samples in Examples 5-1 to 5-6 under the same conditions as those of Examples 1 to 4.

In addition, a lattice volume V was calculated according to the formula V=a²×c from lattice constants a and c measured by performing a reciprocal space mapping (RSM) by an X-Ray diffraction (XRD) method using CuKα1 rays.

### (Resistivity Measurement)

The resistivity of the thin films in Examples 5-1 to 5-6 and Comparative Example 2 was measured while decreasing the temperature under the same conditions as in Example 1. Results are shown in FIG. 8.

As shown in FIG. 8, the thin film in Comparative Example 2 (iridium concentration: 0%) did not exhibit a superconducting transition phenomenon.

In the case of the thin films (iridium concentrations: 6.8%, 6.9%, 7.1%, 8.1%, 11.9%, and 17.5%) in Examples 5-1 to 5-6, a superconducting transition phenomenon was found. It was found from the results that the thin films in Examples 5-1 to 5-6 function as superconductors.

In addition, as shown in FIG. 8, it was found that the superconducting transition temperature (T_{c}) of the thin film (iridium concentration: 6.8%) in Example 5-1 was the highest and was about 119 K. Regarding (Pr_{0.7}Sr_{0.3})(Mn, Ir)O₃ in Examples 5-1 to 5-6, the superconducting transition temperatures are summarized in Table 2.

Regarding the thin film in each example, T_{c}^{on}, T_{c}^{zero}, μ₀H_{c2}^{//}(0), and μ₀H_{c2}^{⊥}(0) were measured. Further, μ₀H_{c2}^{//}(0) was divided by μ₀H_{c2}^{⊥}(0) to calculate an isotropic parameter. The results are also summarized in Table 2. In each of Examples 5-1 to 5-6, since the unit lattice has a cubic structure, it is considered that the sample for which the isotropic parameter is not measured exhibits high isotropy.

FIG. 9 is a graph showing a correlation between a lattice volume and T_{c}^{on} and T_{c}^{zero} of each of the superconductors according to Examples 5-1 to 5-6 and the sample in Comparative Example 2. In the drawing, the measurement results of Comparative Example 2, Example 5-4, Example 5-5, Example 5-1, Example 5-2, Example 5-3, and Example 5-6 are plotted in an order from the smallest lattice volume to largest lattice volume. FIG. 9 was obtained by performing calculation based on lattice constants determined by the ICP analysis. From FIG. 9, in Example 5-1, it was found that T_{c}^{on} and T_{c}^{zero} increased with an increase in lattice volume up to a lattice volume of 58.5 Å³. The lattice volume V is also shown in Table 2. The lattice volume of Comparative Example 2 was 57.78 Å³. Therefore, in the superconductor according to the present embodiment, it is considered that a ratio of the lattice volume of the superconductor after the Ir substitution to a lattice volume of a composition not substituted with an Ir element (Comparative Example 2) is preferably 1.003 times or more and 1.017 times or less. Data in which the symbol “-” is written in the table is data that was not measured. From Table 2, when the A site is (Pr, Sr) and the B site is (Mn, Ir), it is considered that y in the formula (I) corresponding to the Ir concentration is preferably 0.05 or more and 0.1 or less, and more preferably 0.06 or more and 0.075 or less, from the viewpoint of the superconducting transition temperature.

TABLE 2

| | | | | Temperature | Upper critical | Upper critical | | |
|---|---|---|---|---|---|---|---|---|
| | Sr | Ir | Superconducting | at which | field in | field in direction | Isotropic | |
| | concentration | concentration | transition | resistivity | in-plane | perpendicular to | parameter | Lattice |
| | at A site | at B site | temperature | becomes 0 | direction | plane | μ₀H_{c2}^{//}(0)/ | volume |
| | Sr % | Ir % | T_{c}^{on} [K] | T_{c}^{zero} [K] | μ₀H_{c2}^{//}(0) [T] | μ₀H_{c2}^{⊥}(0) [T] | μ₀H_{c2}^{⊥}(0) | V[Å³] |
| Example 5-1 | 35.9 | 6.8 | 119 | 65 | 290 | 249 | 1.17 | 58.32 |
| Example 5-2 | 35.4 | 6.9 | 111 | 60 | 183 | 164 | 1.12 | 58.36 |
| Example 5-3 | 35.5 | 7.1 | 112 | 98 | — | — | — | 58.4 |
| Example 5-4 | 25.9 | 8.1 | 91 | — | — | — | — | 58 |
| Example 5-5 | 22.9 | 11.9 | 86 | 38 | — | — | — | 58.24 |
| Example 5-6 | 22.3 | 17.5 | 98 | — | — | — | — | 58.73 |

### Example 6-1

As a raw material of the superconductor, a composition represented by a composition formula Nd_{0.7}Sr_{0.3}Mn_{0.90}Ir_{0.10}O₃ was set as only one target TA.

Under normal pressure, only the target TA was irradiated with a KrF excimer laser (oscillation wavelength: 248 nm) via a galvanometer mirror for 100 minutes under an environment at 25° C., and a thin film (single crystal film, film thickness: 90 nm) having an iridium concentration adjusted to 7.9% was deposited (epitaxially grown) by the galvanometer scanning pulsed laser deposition method.

A c-plane LSAT substrate having a composition of (LaAlO₃)_{0.3}—(SrAl_{0.5}Ta_{0.5}O₃)_{0.7} was used as a substrate on which a film is to be deposited, and during film deposition, oxygen gas at 50 mTorr (6.7 Pa) was supplied to the film deposition chamber. During the film deposition, a nickel alloy plate was disposed on a surface of the LSAT substrate opposite to the film deposition surface, and the alloy plate was irradiated with an IR laser of 18 W to indirectly heat the LSAT substrate. The surface temperature of the LSAT substrate during film deposition was 530° C.

### Example 6-2

A thin film (single crystal film, film thickness: 80 nm) having an iridium concentration adjusted to 11% was deposited in the same manner as in Example 6-1 except that the composition ratio of the target composition was changed.

### (ICP Analysis)

In order to determine x and y in the formula (I), ICP analysis was performed on the samples in Examples 6-1 and 6-2 under the same conditions as those of Examples 1 to 4. As a result, x=0.315 and y=0.079 in Example 6-1, and y=0.115 in Example 6-2.

### (Resistivity Measurement)

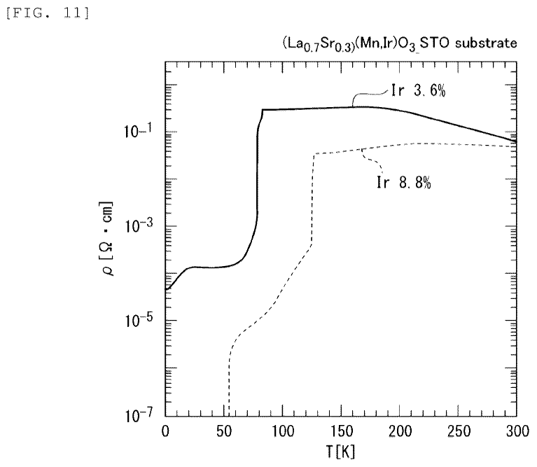

The resistivity of each of the thin films in Examples 6-1 and 6-2 was measured while decreasing the temperature under the same conditions as in Example 1. Results are shown in FIG. 10.

In the case of the thin films (iridium concentrations: 7.9% and 11.5%) in Examples 6-1 and 6-2, a superconducting transition phenomenon was found.

In addition, as shown in FIG. 10, it was found that the superconducting transition temperature (T) of the thin film (iridium concentration: 11.5%) in Example 6-2 was the highest and was about 98 K. The superconducting transition temperatures are summarized in Table 3.

In addition, V, T_{c}^{on}, and T_{c}^{zero} of the thin film in each example were measured. The lattice constants a and c were determined by the same method as in Example 5-1, and the lattice volume V was calculated based on the lattice constants a and c according to the formula V=a²×c. Regarding (Nd_{0.7}Sr_{0.3})(Mn, Ir)O₃ in Examples 6-1 and 6-2, the results are also summarized in Table 3. Data in which the symbol “-” is written in the table is data that was not measured.

TABLE 3

| | Sr | Ir | Super- | Temperature | |
|---|---|---|---|---|---|
| | concen- | concen- | conducting | at which | |
| | tration | tration | transition | resistivity | Lattice |
| | at A site | at B site | temperature | becomes 0 | volume |
| | Sr % | Ir % | T_{c}^{on} [K] | T_{c}^{zero} [K] | V [Å³] |
| EXAMPLE 6-1 | 31.5 | 7.9 | 94 | 34 | 58.24 |
| EXAMPLE 6-2 | — | 11.5 | 98 | 36 | 58.2 |

### Example 7-1

As a raw material of the superconductor, a composition represented by a composition formula La_{0.7}Sr_{0.3}Mn_{0.95}Ir_{0.05}O₃ was set as only one target TA.

Under normal pressure, only the target TA was irradiated with a KrF excimer laser (oscillation wavelength: 248 nm) via a galvanometer mirror for 100 minutes under an environment at 25° C., and a thin film (single crystal film, film thickness: 70 nm) having an iridium concentration adjusted to 3.6% was deposited (epitaxially grown) by the galvanometer scanning pulsed laser deposition method.

A c-plane STO substrate having a composition of SrTiO₃ was used as a substrate on which a film is to be deposited, and during film deposition, oxygen gas at 50 mTorr (6.7 Pa) was supplied to the film deposition chamber. During the film deposition, a nickel alloy plate was placed on a surface of the STO substrate opposite to the film deposition surface, and the alloy plate was irradiated with an IR laser of 18 W to indirectly heat the STO substrate. The surface temperature of the STO substrate during film deposition was 530° C.

### Example 7-2

A thin film (single crystal film, film thickness: 60 nm) having an iridium concentration adjusted to 8.8% was deposited in the same manner as in Example 7-1 except that a composition represented by a composition formula La_{0.7}Sr_{0.3}Mn_{0.90}Ir_{0.10}O₃ was set as the target TA.

### Comparative Example 3

A thin film (single crystal film, film thickness: 70 nm) having an iridium concentration adjusted to 0% was deposited in the same manner as in Example 7-1 except that as a raw material of the superconductor, a composition represented by a composition formula La_{0.7}Sr_{0.3}MnO₃ was set as the target TA.

### (ICP Analysis)

In order to determine x and y in the formula (I) and the lattice constants a and c of the superconductor constituting the thin film, ICP analysis was performed on each of the samples in Examples 7-1 and 7-2 under the same conditions as those of Examples 1 to 4. As a result, y=0.036 in Example 7-1 and y=0.088 in Example 7-2.

In addition, the lattice volume V was calculated according to the formula V=a²×c based on the lattice constants a and c measured by the same method as in the above Example. The lattice constants of Examples 7-1 and 7-2 are shown in Table 4. The lattice volume of Comparative Example 3 was 58.73 Å³.

### (Resistivity Measurement)

The resistivity of each of the thin films in Examples 7-1 and 7-2 was measured while decreasing the temperature under the same conditions as in Example 1. Results are shown in FIG. 11.

In the case of the thin films (iridium concentrations: 3.6% and 8.8%) in Examples 7-1 and 7-2, a superconducting transition phenomenon was found.

In addition, regarding the thin film in each example, T_{c}^{on}, T_{c}^{zero}, μ₀H_{c2}^{//}(0), μ₀H_{c2}^{⊥}(0), and V were measured. Further, μ₀H_{c2}^{//}(0) was divided by μ₀H₂₁^{⊥}(0) to calculate an isotropic parameter. Regarding (La_{0.7}Sr_{0.3})(Mn, Ir)O₃ in Examples 7-1 and 7-2, the results are summarized in Table 4. Data in which the symbol “-” is written in the table is data that was not measured.

TABLE 4

| | Ir | Superconducting | Temperature at | Upper critical | Upper critical field in | Isotropic | |
|---|---|---|---|---|---|---|---|
| | concentration | transition | which resistivity | field in in-plane | direction | parameter | Lattice |
| | at B site | temperature | becomes 0 | direction | perpendicular to plane | μ₀H_{c2}^{//}(0)/ | volume |
| | Ir % | T_{c}^{on} [K] | T_{c}^{zero} [K] | μ₀H_{c2}^{//}(0) [T] | μ₀H_{c2}^{⊥}(0) [T] | μ₀H_{c2}^{⊥}(0) | V[Å³] |
| Example 7-1 | 3.6 | 82 | — | 41 | 45 | 0.92 | 59.18 |
| Example 7-2 | 8.8 | 128 | 53 | 321 | 306 | 1 | 59.38 |

As described above, it can be seen that the superconductor according to the present invention has excellent isotropy and does not require alignment control of the crystal orientation with respect to a magnetic field.

It can be seen that the superconductor according to the present invention has a high T_{c}, and has an increased possibility of practical use as a high-temperature superconductor.

1. A superconductor having a perovskite-type crystal structure and represented by the following formula (I): 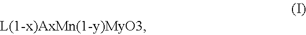
wherein L represents one or more elements selected from lanthanides, A represents one or more elements selected from alkaline earth metals, Mn represents manganese, M represents one or more elements selected from platinum group elements, O represents oxygen, x represents a numerical value of 0 or more and 1 or less, and y represents a numerical value of 0.01 or more and 0.5 or less x in the formula (I).

2. The superconductor according to claim 1, wherein M in the formula (I) represents iridium.

3. The superconductor according to claim 1, wherein L in the formula (I) represents lanthanum.

4. The superconductor according to claim 1, wherein A in the formula (I) represents strontium.

5. The superconductor according to claim 1, which is a bulk body.

6. The superconductor according to claim 1, which is a single crystal film.

7. The superconductor according to claim 1, which is a polycrystalline film.

8. A superconducting wire rod comprising:
the superconductor according to claim 1.

9. A superconducting bulk magnet comprising:
the superconductor according to claim 5.

10. A superconducting coil electromagnet comprising:
the superconducting wire rod according to claim 8.
